(19) United States
(12) Patent Application Publication
(10) Pub. No.: US 2026/0006771 A1
(43) Pub. Date: Jan. 1, 2026

(54) SEMICONDUCTOR DEVICE

(71) Applicant: Samsung Electronics Co., Ltd., Suwon-si (KR)

(72) Inventors: Chulkwon Park, Suwon-si (KR); Bok-Yeon Won, Suwon-si (KR); Jonghyuk Kim, Suwon-si (KR); Honggyun Kim, Suwon-si (KR); Sun Hee Nam, Suwon-si (KR); Joohyeong Lim, Suwon-si (KR)

(21) Appl. No.: 18/982,116

(22) Filed: Dec. 16, 2024

(30) Foreign Application Priority Data
Jul. 1, 2024 (KR) 10-2024-0086423

(51) Int. Cl. H10B 12/00; H01L 21/762; H10B 43/10; H10B 43/27; H10B 43/35; H10B 80/00

(52) U.S. Cl. CPC H10B 12/31; H01L 21/76224; H10B 12/488; H10B 43/27; H10B 43/35; H10B 12/05; H10B 43/10; H10B 80/00

(57) ABSTRACT

A semiconductor device may include a first substrate, a circuit device on the first substrate, an interlayer insulating film on the circuit device, a second substrate on the interlayer insulating film, the second substrate including a first surface adjacent to the interlayer insulating film and a second surface opposite to the first surface, a device isolation trench in the second substrate and adjacent to the second surface, a device isolation structure in the device isolation trench, a through isolation film extending in the second substrate and the device isolation structure, and a through via extending into the through isolation film and electrically connected to the circuit device.

### CROSS-REFERENCE TO RELATED APPLICATIONS

This application claims priority to Korean Patent Application No. 10-2024-0086423, filed in the Korean Intellectual Property Office on Jul. 1, 2024, the entire contents of which are hereby incorporated by reference.

### BACKGROUND OF THE INVENTION

The present disclosure relates to a semiconductor device.

A semiconductor device may be a core component used to control or amplify an electrical signal in an electronic device, and various types of semiconductor devices may be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

With the development of the electronics industry, the performance and function requirements of the electronic devices are increasing. Accordingly, demand is increasing for semiconductor devices having high-performance characteristics, and the integration density of the semiconductor devices is increasing to meet these demands. Accordingly, new transistor structures such as transistors with vertical channels and vertical stack transistors have been proposed.

### SUMMARY OF THE INVENTION

The present disclosure provides a semiconductor device with improved reliability and integration density.

According to some embodiments of the present disclosure, the device isolation structure may be disposed around the through isolation film, thereby reducing stress applied to the substrate of the transistor. Accordingly, the reliability of the semiconductor device may be improved.

According to some embodiments of the present disclosure, the transistor may be disposed between the device isolation structure surrounding the through isolation film and the adjacent device isolation structure, thereby improving the integration density of the semiconductor device.

According to some embodiments of the present disclosure, a semiconductor device is provided that includes a first substrate, a circuit device on the first substrate, an interlayer insulating film on the circuit device, a second substrate on the interlayer insulating film, wherein the second substrate includes a first surface adjacent to the interlayer insulating film and a second surface opposite to the first surface, a device isolation trench in the second substrate and adjacent to the second surface, a device isolation structure in the device isolation trench, a through isolation film extending in the second substrate and the device isolation structure, and a through via extending into the through isolation film and electrically connected to the circuit device.

According to some embodiments of the present disclosure, a semiconductor device is provided that includes a first substrate, a circuit device on the first substrate, an interlayer insulating film on the first substrate and the circuit device, a second substrate on the interlayer insulating film, wherein the second substrate includes a first surface in contact with the interlayer insulating film and a second surface opposite to the first surface, a through isolation film extending in the second substrate, a first device isolation structure in the second substrate and at least partially surrounding the through isolation film, wherein the first device isolation structure includes a first liner film, a second liner film, and a filling film that are sequentially stacked, and a through via extending into the through isolation film and electrically connected to the circuit device.

According to some embodiments of the present disclosure, a semiconductor device is provided that includes a first substrate, a circuit device on the first substrate, wherein the circuit device includes a plurality of cell channel patterns stacked in a first direction perpendicular to an upper surface of the first substrate, a word line on the plurality of cell channel patterns and extending in a second direction parallel to the upper surface of the first substrate, and a bit line, an interlayer insulating film on the first substrate and the circuit device, a second substrate on the interlayer insulating film, wherein the second substrate includes a first surface in contact with the interlayer insulating film and a second surface opposite to the first surface, a device isolation trench in the second substrate and adjacent to the second surface, a device isolation structure in the device isolation trench, wherein the device isolation structure includes a first liner film, a second liner film, and a filling film that are sequentially stacked, a through isolation film extending in the second substrate and adjacent to the device isolation structure, and a through via extending into the through isolation film and electrically connected to the word line, wherein the device isolation structure at least partially surrounds the through isolation film.

### BRIEF DESCRIPTION OF THE DRAWINGS

The above and other embodiments and features of the present disclosure will become more apparent by describing in detail example embodiments thereof with reference to the accompanying drawings, in which:

FIG. 1 is an example plan view provided to explain a semiconductor device according to some embodiments;

FIG. 2 is a cross-sectional view taken along line A-A of FIG. 1;

FIGS. 3 to 5 are enlarged views provided to explain a region Q1 of FIG. 2;

FIGS. 6 to 8 are diagrams provided to explain a semiconductor device according to some embodiments;

FIG. 9 is a diagram provided to explain a semiconductor device according to some embodiments;

FIG. 10 is a diagram provided to explain a semiconductor device according to some embodiments;

FIG. 11 is a diagram provided to explain a semiconductor device according to some embodiments;

FIGS. 12 and 13 are diagrams provided to explain a semiconductor device according to some embodiments;

FIG. 14 is a diagram provided to explain a circuit device included in the semiconductor device according to some embodiments;

FIGS. 15 to 20 are diagrams illustrating intermediate stages of manufacturing a semiconductor device, which are provided to explain a method for manufacturing a semiconductor device according to some embodiments.

### DETAILED DESCRIPTION

Hereinafter, a semiconductor device and a method for manufacturing the same according to example embodiments of the present disclosure will be described in detail with reference to the drawings.

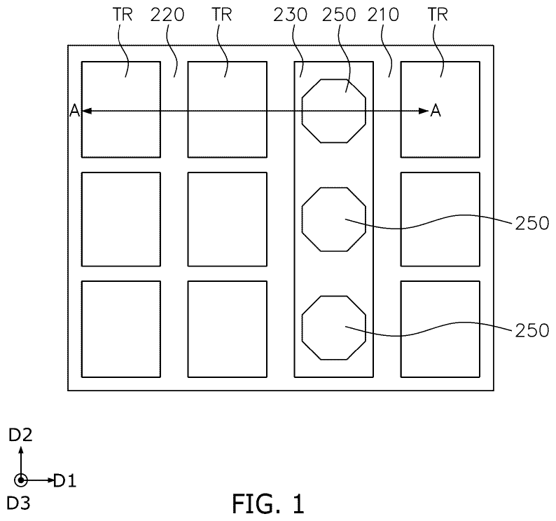

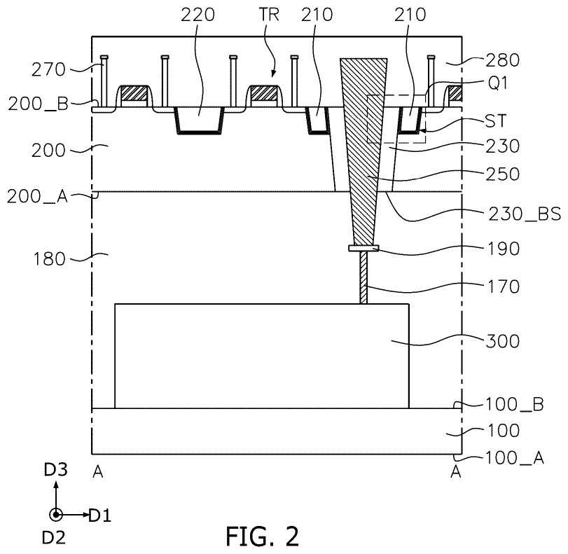

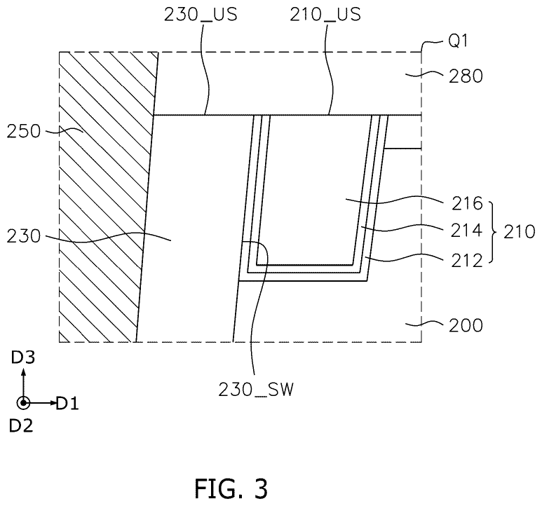

FIG. 1 is an example plan view provided to explain a semiconductor device according to some embodiments. FIG. 2 is a cross-sectional view taken along line A-A of FIG. 1. FIGS. 3 to 5 are enlarged views provided to explain a region Q1 of FIG. 2.

Referring to FIGS. 1 to 5, a semiconductor device according to some embodiments may include a first substrate 100, a first interlayer insulating film 180, a second substrate 200, a device isolation trench ST, device isolation structures 210 and 220, a through isolation film 230, a through via 250, a second interlayer insulating film 280, a transistor TR, and a circuit device 300.

The first substrate 100 may be a semiconductor substrate. For example, the first substrate 100 may include silicon (Si), silicon germanium (SiGe), indium antimonide (InSb), lead telluride (PbTe), indium arsenide (InAs), indium phosphide (INP), gallium arsenide (GaAs), gallium antimonide (GaSb), etc. However, embodiments of the present disclosure are not limited thereto.

The first substrate 100 may include a first surface 100_A and a second surface 100_B opposite the first surface 100_A. The second surface 100_B of the first substrate 100 may be a surface on which the circuit device 300 is disposed. The second surface 100_B of the first substrate 100 may be referred to as a front side of the first substrate 100. The first surface 100_A of the first substrate 100 may be referred to as a back side of the first substrate 100.

The circuit device 300 may be disposed on the second surface 100_B of the first substrate 100. The circuit device 300 may include a memory circuit device. For example, the circuit device 300 may include a dynamic random access memory (DRAM) and a flash memory. The dynamic random access memory may include a vertical channel DRAM, a vertical stacked DRAM, etc., and the flash memory may include a three-dimensional vertical NAND flash memory. However, embodiments of the present disclosure are not limited thereto.

In some embodiments, the circuit device 300 may further include a non-memory circuit device. For example, the circuit device 300 may further include a logic circuit. The logic circuit may control a plurality of memory cells. In some embodiments, the circuit device 300 does not include a memory circuit device and may include only a non-memory circuit device.

The first interlayer insulating film 180 may be disposed on the second surface 100_B of the first substrate 100. The first interlayer insulating film 180 may be on (e.g., may cover) the circuit device 300. The first interlayer insulating film 180 may include an insulating material. For example, the first interlayer insulating film 180 may include at least one of silicon oxide, silicon nitride, or silicon oxynitride.

A lower contact via 170 may be disposed in the first interlayer insulating film 180. The lower contact via 170 may be connected to the circuit device 300. For example, the lower contact via 170 may be electrically connected to a word line or a bit line of the circuit device 300. The circuit device 300 may be electrically connected to a lower wiring structure 190 through the lower contact via 170.

Although the first interlayer insulating film 180 is illustrated as a single layer, embodiments of the present disclosure are not limited thereto. For example, the first interlayer insulating film 180 may include a bonding layer and a filling insulating film. The filling insulating film may be on (e.g., may cover) the circuit device 300. The bonding layer may be disposed on the filling insulating film.

The bonding layer may be positioned at the uppermost portion of the first interlayer insulating film 180. For example, an upper surface of the bonding layer may define an upper surface of the first interlayer insulating film 180. The upper surface of the bonding layer may be in contact with a first surface 200_A of the second substrate 200. The bonding layer may include a dielectric material. For example, the bonding layer may include silicon oxide, silicon nitride, silicon oxynitride, etc. In some embodiments, a boundary surface between the bonding layer and the filling insulating film may not be distinguished.

The second substrate 200 may be disposed on the first interlayer insulating film 180. The second substrate 200 may be a semiconductor substrate. For example, the second substrate 200 may include silicon (Si), silicon germanium (SiGe), indium antimonide (InSb), lead telluride (PbTe), indium arsenide (InAs), indium phosphide (INP), gallium arsenide (GaAs), gallium antimonide (GaSb), etc. However, embodiments of the present disclosure are not limited thereto.

The second substrate 200 may include the first surface 200_A and a second surface 200_B opposite the first surface 200_A. The first surface 200_A of the second substrate 200 may be a surface adjacent to the first interlayer insulating film 180. In some embodiments, the first surface 200_A of the second substrate 200 may be in contact with the first interlayer insulating film 180. The first surface 200_A of the second substrate 200 may be opposite the second surface 100_B of the first substrate 100. The second surface 200_B of the second substrate 200 may be referred to as a front side of the second substrate 200. The first surface 200_A of the second substrate 200 may be referred to as a back side of the second substrate 200.

The device isolation trench ST may be disposed on the second surface 200_B of the second substrate 200. The device isolation trench ST may be recessed from the second surface 200_B of the second substrate 200 toward the first substrate 100. For example, the device isolation trench ST may be in the second substrate 200 adjacent to the second surface 200_B. The device isolation trench ST may isolate transistors TR. For example, at least some of a plurality of transistors TR may be disposed to be spaced apart from each other by the device isolation trench ST.

A first device isolation structure 210 may be disposed on the second substrate 200. The first device isolation structure 210 may be disposed on the device isolation trench ST. The first device isolation structure 210 may be in (e.g., may fill) the device isolation trench ST. The first device isolation structure 210 may surround the through isolation film 230. It will be understood that “an element A surrounds an element B” (or similar language) as used herein means that the element A is at least partially around the element B but does not necessarily mean that the element A completely encloses the element B. For example, the first device isolation structure 210 may be on opposing side surfaces of the through isolation film 230. The first device isolation structure 210 may overlap a portion of the through isolation film 230 in the first direction D1. As used herein, “an element A overlaps an element B in a direction X” (or similar language) means that there is at least one straight line that extends in the direction X and intersects both the elements A and B. The first device isolation structure 210 may include an insulating material.

A first direction D1 may intersect a second direction D2. Each of the first and second directions D1 and D2 may be a direction parallel to the second surface 200_B of the second substrate 200. A third direction D3 may intersect each of the first and second directions D1 and D2. The third direction D3 may be a direction perpendicular to the second surface 200_B of the second substrate 200.

The through isolation film 230 may penetrate the first device isolation structure 210. For example, the through isolation film 230 may extend in the second substrate 200 and the first device isolation structure 210 and may be adjacent to the first device isolation structure 210. The through isolation film 230 may penetrate the second substrate 200. For example, the through isolation film 230 may penetrate the first surface 200_A and the second surface 200_B of the second substrate 200 in the third direction D3. That is, the through isolation film 230 may extend in the second substrate 200 in the third direction D3 from the first surface 200_A to the second surface 200_B. An upper portion of the through isolation film 230 may be surrounded by the first device isolation structure 210. In some embodiments, a lower surface 230_BS of the through isolation film 230 may be disposed on the same plane as (i.e., may be coplanar with) the first surface 200_A of the second substrate 200.

In some embodiments, when viewed in a plan view as illustrated in FIG. 1, the through isolation film 230 may extend in the second direction D2. A plurality of transistors TR may be disposed on both (i.e., opposing) sides of the through isolation film 230 in the first direction D1. A direction in which active regions of a plurality of transistors TR extend may be the same as a direction in which the through isolation film 230 extends. That is, the active regions of the plurality of transistors TR may extend in the second direction D2.

The through isolation film 230 may include an insulating material. For example, the through isolation film 230 may include silicon oxide.

The first device isolation structure 210 and the through isolation film 230 will be described in detail with reference to FIGS. 2 and 3.

The first device isolation structure 210 may include a first liner film 212, a second liner film 214, and a filling film 216.

The first liner film 212 may be disposed along the device isolation trench ST. The first liner film 212 may be disposed along a bottom surface and a sidewall of the device isolation trench ST. In some embodiments, at least a portion of the first liner film 212 may be in contact with a sidewall 230_SW of the through isolation film 230. A portion of the first liner film 212 may extend along the sidewall 230_SW of the through isolation film 230.

The second liner film 214 may be disposed on the first liner film 212. The second liner film 214 may extend along a profile of the first liner film 212. A portion of the second liner film 214 may extend along a sidewall 230_SW of the through isolation film 230. In some embodiments, the first liner film 212 and the second liner film 214 may be conformally formed. However, embodiments of the present disclosure are not limited thereto.

The filling film 216 may be disposed on the second liner film 214. The filling film 216 may be in (e.g., may fill) the device isolation trench ST. For example, the filling film 216 may fill the remaining portion in the device isolation trench ST other than the portion in which the first liner film 212 and the second liner film 214 are disposed. That is, the first liner film 212, the second liner film 214, and the filling film 216 may be sequentially stacked on (i.e., in) the device isolation trench ST.

In some embodiments, an upper surface 210_US of the first device isolation structure 210 may be disposed on the same plane as an upper surface 230_US of the through isolation film 230. The upper surface 230_US of the through isolation film 230 may be disposed on the same plane as the second surface 200_B of the second substrate 200. The upper surface 210_US of the first device isolation structure 210 may be disposed on the same plane as the second surface 200_B of the second substrate 200.

For example, the first liner film 212 may include silicon oxide. For example, the second liner film 214 may include silicon nitride. For example, the filling film 216 may include silicon oxide.

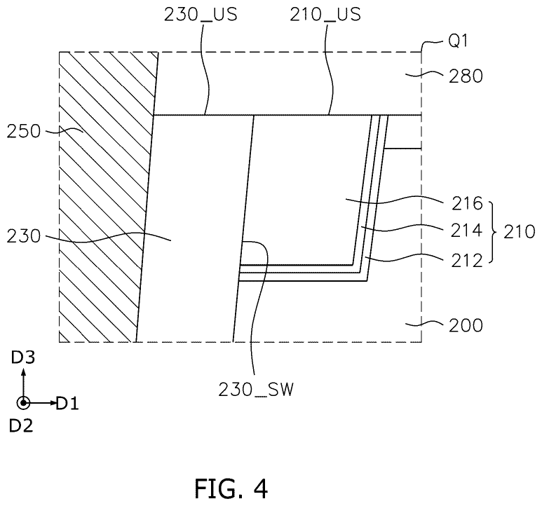

In some embodiments, the first device isolation structure 210 may be in contact with the through isolation film 230. For example, as illustrated in FIG. 4, in some embodiments, a portion of each of the first liner film 212, the second liner film 214, and the filling film 216 may be in contact with the sidewall 230_SW of the through isolation film 230. The through isolation film 230 may penetrate each of the first liner film 212, the second liner film 214, and the filling film 216.

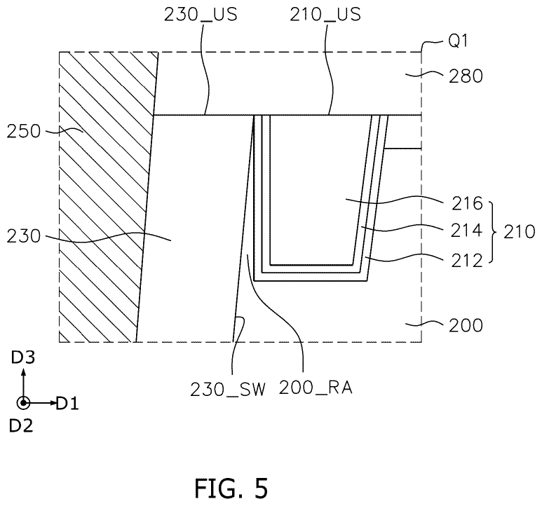

In some embodiments, as illustrated in FIG. 5, the second substrate 200 may include a remaining region 200_RA. The remaining region 200_RA may be defined as a region of the second substrate 200 disposed between the first device isolation structure 210 and the through isolation film 230. That is, the remaining region 200_RA may overlap the first device isolation structure 210 and the through isolation film 230 in the first direction D1. The remaining region 200_RA may be in contact with the sidewall 230_SW of the through isolation film 230 and the first liner film 212. The remaining region 200_RA may be a portion of the second substrate 200 that is not removed in the process of forming the device isolation trench ST.

In addition, referring to FIGS. 1 to 5, the through via 250 may penetrate the through isolation film 230, the first device isolation structure 210, and the second substrate 200. The through via 250 may penetrate the through isolation film 230 in the third direction D3. The second interlayer insulating film 280 may be disposed on the through via 250. A lower portion of the through via 250 may penetrate the second substrate 200 and may be disposed in the first interlayer insulating film 180. One end of the through via 250 may be connected to the lower wiring structure 190. The through via 250 may have a tapered shape with its width reduced toward the first substrate 100. However, embodiments of the present disclosure are not limited thereto.

The through via 250 may not be in contact with the first device isolation structure 210. At least a portion of the through isolation film 230 may be disposed between the first device isolation structure 210 and the through via 250. The through via 250 may be spaced apart from the first device isolation structure 210 by the through isolation film 230.

Although not illustrated, an upper portion of the through via 250 may be connected to an upper wiring structure. The upper wiring structure may electrically connect the transistor TR to the through via 250. That is, the transistor TR may be electrically connected to the circuit device 300 through the through via 250.

The through via 250 may include a conductive material. For example, the through via 250 may include at least one of aluminum (Al), tungsten (W), cobalt (Co), ruthenium (Ru), silver (Ag), gold (Au), manganese (Mn), or molybdenum (Mo). Although the through via 250 is illustrated as a single layer, embodiments of the present disclosure are not limited thereto. For example, the through via 250 may include a barrier layer and a filling layer.

A second device isolation structure 220 may be disposed on the second substrate 200. The second device isolation structure 220 may be disposed on the device isolation trench ST. The through isolation film 230 may not be disposed on the second device isolation structure 220. The transistor TR may be disposed on at least one side of the second device isolation structure 220. At least some of a plurality of transistors TR may be disposed to be spaced apart from each other by the second device isolation structure 220.

The second device isolation structure 220 may be disposed to be spaced apart from the first device isolation structure 210 in the first direction D1. The second device isolation structure 220 may be the closest device isolation structure to the first device isolation structure 210. For example, the second device isolation structure 220 may be adjacent to the first device isolation structure 210 in the first direction D1. In some embodiments, the transistor TR may be disposed between the second device isolation structure 220 and the first device isolation structure 210. Accordingly, the integration density of the semiconductor device may be improved.

The second device isolation structure 220 may include a plurality of layers. The plurality of layers of the second device isolation structure 220 may be the same as the first liner film 212, the second liner film 214, and the filling film 216 of the first device isolation structure 210.

A plurality of transistors TR may be disposed on the second surface 200_B of the second substrate 200. The transistor TR may include a gate insulating film, a gate electrode, and a source and drain region. In some embodiments, the transistor TR may include an active region extending in the second direction D2. Although the transistor TR is illustrated as a planar transistor (e.g., a planar MOSFET), it will be understood that this is an example and embodiments of the present disclosure are not limited thereto. For example, the transistor TR may be a FinFET or a gate-all-around FET (GAAFET).

An upper contact via 270 may be disposed on the source and drain region of the transistor TR. The upper contact via 270 may be connected to the through via 250 through the upper wiring structure. The plurality of transistors TR may configure a logic circuit for controlling the circuit device 300. For example, the logic circuit may be on the second surface 200_B of the second substrate 200.

The second interlayer insulating film 280 may be disposed on the second surface 200_B of the second substrate 200. The second interlayer insulating film 280 may be on (e.g., may cover) the plurality of transistors TR and the through via 250. The upper wiring structure may be disposed in the second interlayer insulating film 280. The second interlayer insulating film 280 may include an insulating material. For example, the second interlayer insulating film 280 may include at least one of silicon oxide, silicon nitride, or silicon oxynitride.

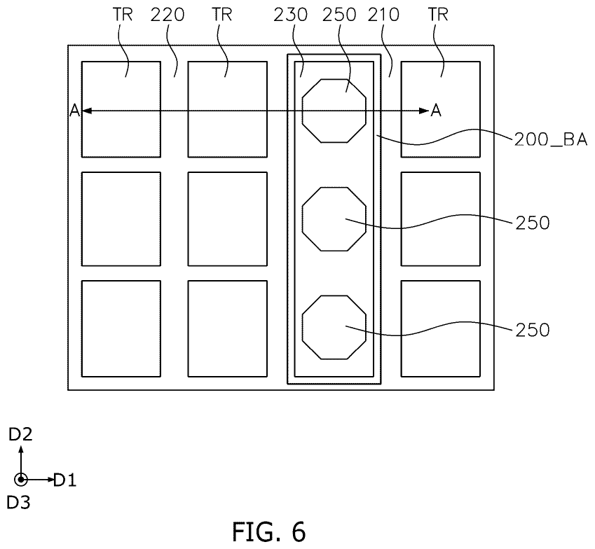

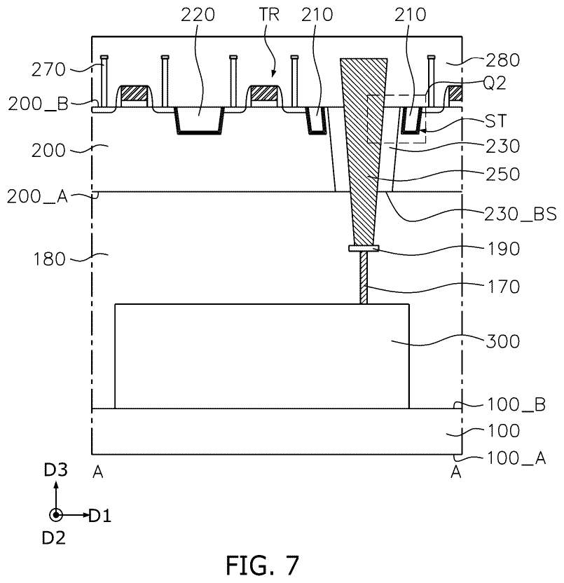

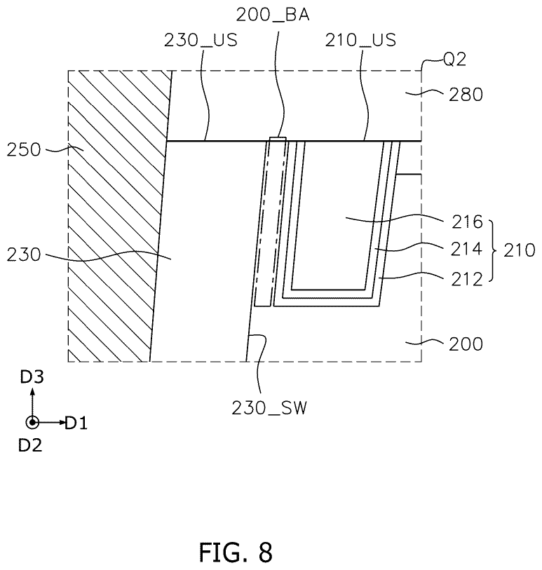

FIGS. 6 to 8 are diagrams provided to explain a semiconductor device according to some embodiments. For reference, FIG. 6 is an example plan view provided to explain a semiconductor device according to some embodiments, FIG. 7 is a cross-sectional view taken along line A-A of FIG. 6, and FIG. 8 is an enlarged view provided to explain a Q2 region of FIG. 7. For convenience of description, differences from the semiconductor device described with reference to FIGS. 1 to 5 will be mainly described.

Referring to FIGS. 6 to 8, in the semiconductor device according to some embodiments, the second substrate 200 may include a buffer region 200_BA.

When viewed in a plan view, the buffer region 200_BA may surround the through isolation film 230, and the first device isolation structure 210 may surround the buffer region 200_BA. The buffer region 200_BA may be defined as a region of the second substrate 200 disposed between the first device isolation structure 210 and the through isolation film 230. The buffer region 200_BA may overlap the first device isolation structure 210 and the through isolation film 230 in the first direction D1.

The first device isolation structure 210 may not be in contact with the through isolation film 230. The first device isolation structure 210 may be spaced apart from the through isolation film 230 by the buffer region 200_BA. The buffer region 200_BA may be in contact with each of the sidewall 230_SW of the through isolation film 230 and the first liner film 212.

In the process of forming the through isolation film 230 on the device isolation trench ST, stress may be applied to the second substrate 200 and a lattice of the second substrate 200 may be dislocated. Furthermore, stress may be applied to the second substrate 200 in the process of forming the filling film 216 in the device isolation trench ST and/or during the heat treatment process, causing the lattice of the second substrate 200 to be dislocated. In the semiconductor device according to some embodiments, the second substrate 200 includes the buffer region 200_BA, so that dislocation of the lattice of the second substrate 200 may be reduced. Accordingly, the reliability of the semiconductor device may be improved.

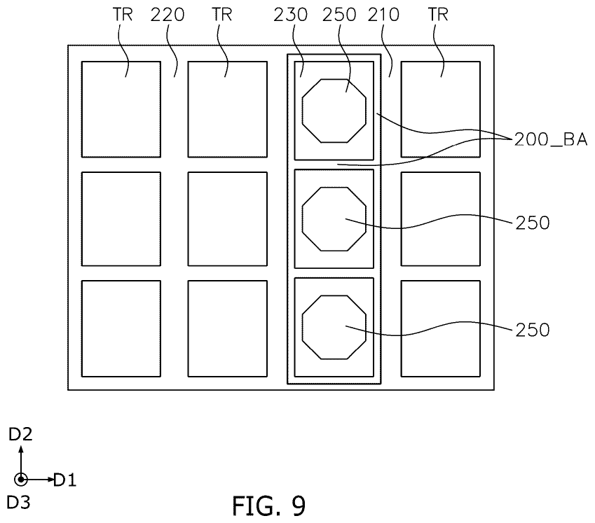

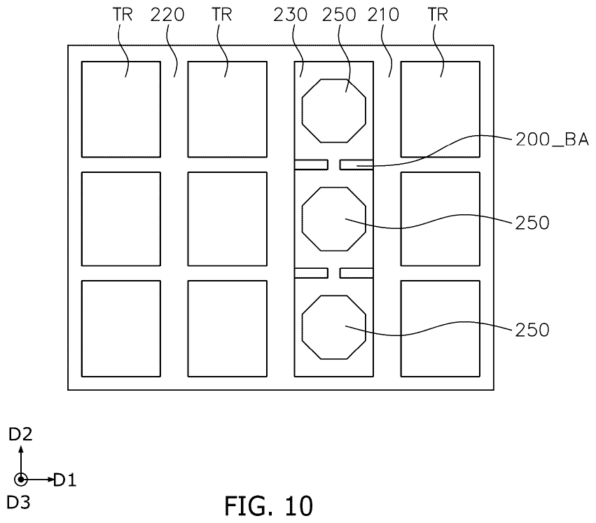

FIG. 9 is a diagram provided to explain a semiconductor device according to some embodiments. FIG. 10 is a diagram provided to explain a semiconductor device according to some embodiments. For reference, FIGS. 9 and 10 are each an example plan view provided to explain a semiconductor device according to some embodiments. For convenience of description, differences from the semiconductor device described with reference to FIGS. 6 to 8 will be mainly described.

Referring to FIGS. 9 and 10, in the semiconductor device according to some embodiments, the second substrate 200 may include the buffer region 200_BA.

In some embodiments, when viewed in a plan view, as illustrated in FIG. 9, the buffer region 200_BA may divide the through isolation film 230. For example, the through isolation film 230 may be divided into three by the buffer region 200_BA. In other words, three portions or regions of the through isolation film 230 may be spaced apart from each other (e.g., in the second direction D2), with the buffer region 200_BA therebetween. One through via 250 may be disposed in the through isolation film 230. In other words, the buffer region 200_BA may be disposed between the through vias 250 aligned in the second direction D2. The buffer region 200_BA may surround the through isolation film 230 and the through via 250.

In some embodiments, when viewed in a plan view, as illustrated in FIG. 10, the buffer region 200_BA may be disposed between the through vias 250 aligned in the second direction D2 and may not be disposed around the through isolation film 230. The buffer region 200_BA may be disposed to be spaced apart from each other in the first direction D1 on the through isolation film 230. However, embodiments of the present disclosure are not limited thereto. For example, the buffer region 200_BA between the through vias 250 may be connected in the first direction D1 as illustrated in FIG. 9.

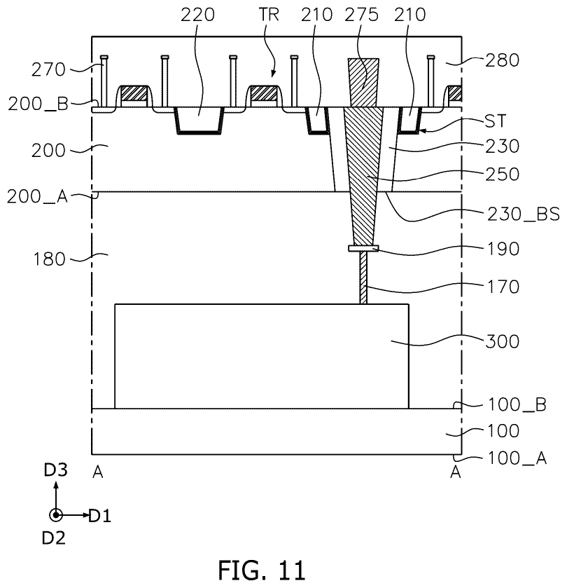

FIG. 11 is a diagram provided to explain a semiconductor device according to some embodiments. For reference, FIG. 11 is an example cross-sectional view provided to explain a semiconductor device according to some embodiments. For convenience of description, differences from the semiconductor device described with reference to FIGS. 1 to 5 will be mainly described.

Referring to FIG. 11, in the semiconductor device according to some embodiments, a through contact via 275 may be disposed on the through via 250.

The through via 250 may penetrate the through isolation film 230, the first device isolation structure 210, and the second substrate 200. The through via 250 may penetrate the through isolation film 230 in the third direction D3. An upper surface of the through via 250 may be disposed on the same plane as the second surface 200_B of the second substrate 200. A lower portion of the through via 250 may penetrate the second substrate 200 and may be disposed in the first interlayer insulating film 180. One end of the through via 250 may be connected to the lower wiring structure 190. Another end of the through via 250 may be connected to the through contact via 275. The through via 250 may have a tapered shape with its width reduced toward the first substrate 100. However, embodiments of the present disclosure are not limited thereto.

The through contact via 275 may be disposed on the upper surface of the through via 250. The through contact via 275 may be connected to the through via 250. The through contact via 275 may be electrically connected to the transistor TR through the upper wiring structure. The through contact via 275 may include a conductive material.

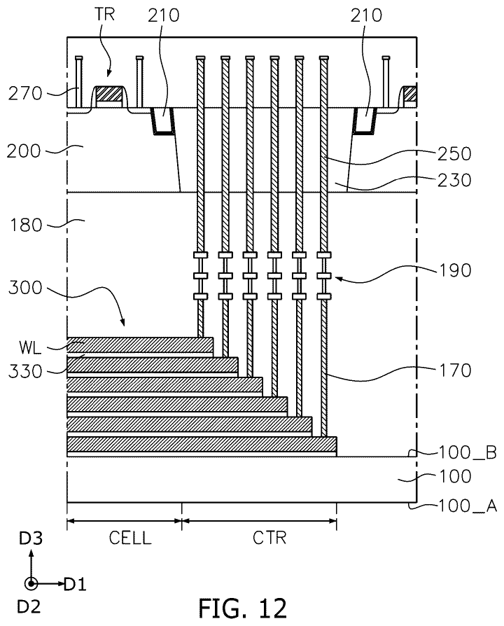

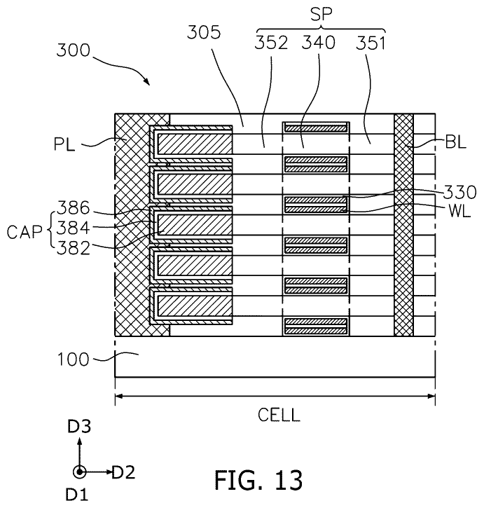

FIGS. 12 and 13 are diagrams provided to explain a semiconductor device according to some embodiments. For reference, FIGS. 12 and 13 are each an example cross-sectional view provided to explain a semiconductor device according to some embodiments. For convenience of description, differences from the semiconductor device described with reference to FIGS. 1 to 5 will be mainly described.

Referring to FIGS. 12 and 13, in the semiconductor device according to some embodiments, the circuit device 300 may be a memory device including a stacked channel. The circuit device 300 may include a cell insulating film 305, a gate insulating film 330, a capacitor structure CAP, a cell semiconductor pattern SP, a word line WL, a plate electrode PL, and a bit line BL.

The cell semiconductor pattern SP may be disposed on a cell region CELL of the circuit device 300. A plurality of cell semiconductor patterns SP and a plurality of cell insulating films 305 may be alternately stacked on the second surface 100_B of the first substrate 100. The cell semiconductor pattern SP may have a line shape, a bar shape, or a column shape extending in the second direction D2. The cell semiconductor pattern SP may penetrate the word line WL.

For example, the cell semiconductor pattern SP may include silicon, germanium, silicon-germanium, indium gallium zinc oxide (IGZO), or indium tin zinc oxide (ITZO). In addition, for example, the cell semiconductor pattern SP may include a two-dimensional semiconductor material.

The cell semiconductor pattern SP may include a cell channel pattern 340, a first source and drain pattern 351, and a second source and drain pattern 352.

The cell channel pattern 340 may be disposed between the first source and drain pattern 351 and the second source and drain pattern 352. The cell channel pattern 340 may be disposed between the word lines WL (e.g., in the third direction D3). For example, the cell channel patterns 340 may be stacked in the third direction D3, and the word lines WL may be on the cell channel patterns 340. In some embodiments, the word line WL may have a structure (e.g., a gate-all-around structure) that completely surrounds the cell channel pattern 340.

The first source and drain pattern 351 may be disposed at one end of the cell channel pattern 340. The first source and drain pattern 351 may be connected to the bit line BL. The second source and drain pattern 352 may be disposed at the other end of the cell channel pattern 340. The second source and drain pattern 352 may be connected to the capacitor structure CAP.

The first source and drain pattern 351 and the second source and drain pattern 352 may have a first conductivity type (e.g., an n-type). The cell channel pattern 340 may not be doped or may have a second conductivity type (e.g., a p-type) different from the first conductivity type.

Each of a plurality of word lines WL may extend in the first direction D1 parallel to the second surface 100_B of the first substrate 100. Each of the plurality of word lines WL may surround the cell channel pattern 340. The plurality of word lines WL may be disposed in the cell region CELL and the contact region CTR. The plurality of word lines WL may have a step shape (e.g., a staircase shape) on the contact region CTR. Each of the plurality of word lines WL may include a pad portion with an upper surface exposed due to the step shape. The lower contact via 170 may be connected to the pad portion of the word line WL.

The word line WL may include a conductive material. For example, the word line WL may include at least one of a doped semiconductor material, a conductive metal nitride, or a metal-semiconductor compound, but embodiments of the present disclosure are not limited thereto.

The gate insulating film 330 may be disposed between the cell channel pattern 340 and the word line WL. The gate insulating film 330 may surround the cell channel pattern 340. The word line WL may be disposed on the gate insulating film 330. The gate insulating film 330 may include at least one of a high-k insulating film, a silicon oxide film, a silicon nitride film, or a silicon oxynitride film.

The cell insulating film 305 may be disposed between the cell semiconductor patterns SP stacked in the third direction D3. A portion of the cell insulating film 305 may be disposed between the word lines WL adjacent to each other in the third direction D3. The cell insulating film 305 may electrically isolate the word lines WL. The cell insulating film 305 may include an insulating material.

The capacitor structure CAP may include a first electrode 382, a dielectric film 384, and a second electrode 386. The first electrode 382 may be disposed at one end of the cell semiconductor pattern SP. The first electrode 382 may be connected to the second source and drain pattern 352. The first electrode 382 may have a pillar shape extending in the second direction D2. The first electrode 382 may include at least one of a metal material, a metal nitride layer, or a metal silicide.

The dielectric film 384 may be disposed between the first electrode 382 and the second electrode 386. The dielectric film 384 may be disposed along a profile of the first electrode 382. For example, the dielectric film 384 may include at least one of silicon oxide, silicon nitride, silicon oxynitride, metal oxide, or a dielectric material having a perovskite structure.

The second electrode 386 may be disposed on the dielectric film 384. The second electrode 386 may extend along the dielectric film 384. The second electrode 386 may be connected to the plate electrode PL. For example, the second electrode 386 may include at least one of impurity-doped silicon, a metal material, a metal nitride layer, or a metal silicide. In some embodiments, the second electrode 386 may include substantially the same material as the first electrode 382.

The plate electrode PL may extend in the first direction D1 and the third direction D3. The plate electrode PL may be in contact with the second electrode 386. The plate electrode PL may be electrically connected to a plurality of second electrodes 386 disposed in the first direction D1. The plate electrode PL may include a conductive material. For example, the plate electrode PL may include at least one of a doped semiconductor material, a conductive metal nitride, a metal, or a metal-semiconductor compound.

The bit line BL may be disposed on the first substrate 100. The bit lines BL may extend in the first direction D1. For example, the bit lines BL may penetrate the plurality of stacked cell semiconductor patterns SP. The cell semiconductor patterns SP may be connected to the bit lines BL. For example, the bit line BL may be electrically connected to the first source and drain pattern 351 of the cell semiconductor pattern SP.

The lower contact via 170 may be disposed in the first interlayer insulating film 180. The lower contact via 170 may be connected to the circuit device 300. For example, the lower contact via 170 may be connected to the word line WL of the circuit device 300. The circuit device 300 may be electrically connected to the lower wiring structure 190 through the lower contact via 170.

The through via 250 may penetrate the through isolation film 230. The through via 250 may extend in the third direction D3. A plurality of through vias 250 may be disposed in one through isolation film 230. The plurality of through vias 250 may be electrically connected to the lower wiring structure 190. Although not illustrated, the plurality of through vias 250 may be electrically connected to the transistor TR by the upper wiring structure.

When viewed in a cross-sectional view, the width of the through via 250 is illustrated to be constant in FIG. 12, but embodiments of the present disclosure are not limited thereto. For example, the width of the through via 250 may decrease toward the first substrate 100.

Although the through via 250 is illustrated to be connected to the word line WL through the lower wiring structure 190 and the lower contact via 170, it will be understood that this is an example and embodiments of the present disclosure are not limited thereto. For example, in some embodiments, the through via 250 may be electrically connected to the bit line BL, the plate electrode PL, etc. of the circuit device 300 through the lower wiring structure 190.

The transistor TR may be disposed on the second substrate 200. The transistor TR may configure a logic circuit for controlling the circuit device 300. For example, the logic circuit may include various circuits such as a command decoder, a control logic, an address buffer, a row decoder, a column decoder, a sense amplifier, a sub word line driver, and a data input and output circuit.

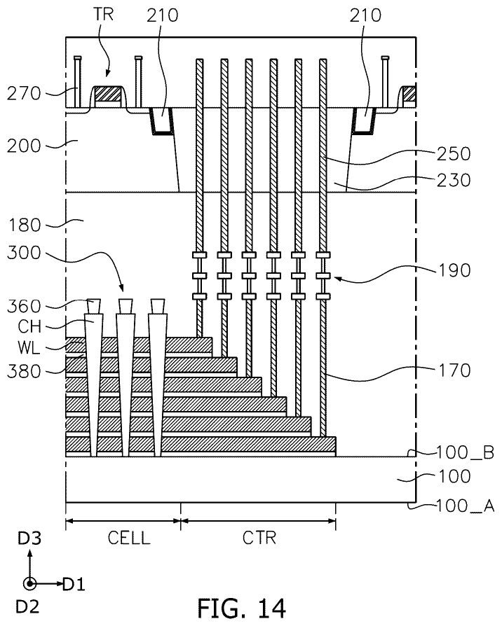

FIG. 14 is a diagram provided to explain a circuit device included in the semiconductor device according to some embodiments. For reference, FIG. 14 is an example cross-sectional view provided to explain a semiconductor device according to some embodiments. For convenience of description, differences from the semiconductor device described with reference to FIGS. 1 to 5 will be mainly described.

Referring to FIG. 14, in the semiconductor device according to some embodiments, the circuit device 300 may be, for example, a flash memory device. The circuit device 300 may include a channel structure CH, a word line WL, and a bit line contact 360.

The plurality of word lines WL and a plurality of mold insulating films 380 may be alternately stacked on the second surface 100_B of the first substrate 100 (e.g., in the third direction D3). The channel structure CH may penetrate the plurality of word lines WL and the mold insulating films 380. The channel structure CH may extend in the third direction D3.

Although not illustrated, the channel structure CH may include a channel semiconductor pattern, an information storage film, etc.

The channel semiconductor pattern may extend in the third direction D3. For example, the channel semiconductor pattern may include a semiconductor material such as single crystal silicon, polycrystalline silicon, an organic semiconductor material, and/or a carbon nanostructure.

The information storage film may be disposed between the channel semiconductor pattern and each of the word lines WL. The information storage film may be formed of multiple films. The information storage film may include a tunnel insulating film, a charge storage film, and a blocking insulating film. In some embodiments, the information storage film may include an oxide-nitride-oxide (ONO) structure.

The bit line contact 360 may be connected to the channel structure CH. For example, the bit line contact 360 may be disposed on a channel pad of the channel structure CH. Although not illustrated, a bit line may be electrically connected to the bit line contact 360. The bit line may extend in a direction intersecting the word line WL.

The lower contact via 170 may be disposed in the first interlayer insulating film 180. The lower contact via 170 may be connected to the circuit device 300. For example, the lower contact via 170 may be connected to the word line WL of the circuit device 300. The circuit device 300 may be electrically connected to the lower wiring structure 190 through the lower contact via 170.

The through via 250 may penetrate the through isolation film 230. The through via 250 may extend in the third direction D3. A plurality of through vias 250 may be disposed in one through isolation film 230. The plurality of through vias 250 may be electrically connected to the lower wiring structure 190. Although not illustrated, the plurality of through vias 250 may be electrically connected to the transistor TR by the upper wiring structure.

When viewed in a cross-sectional view, the width of the through via 250 is illustrated to be constant in FIG. 14, but embodiments of the present disclosure are not limited thereto. For example, the width of the through via 250 may decrease toward the first substrate 100.

Although the through via 250 is illustrated to be connected to the word line WL through the lower wiring structure 190 and the lower contact via 170, it will be understood that this is an example and embodiments of the present disclosure are not limited thereto. For example, in some embodiments, the through via 250 may be electrically connected to the bit line of the circuit device 300 through the lower wiring structure 190.

The transistor TR may be disposed on the second substrate 200. The transistor TR may configure a logic circuit for controlling the circuit device 300. For example, the logic circuit may include a row decoder, a page buffer, a control circuit, etc.

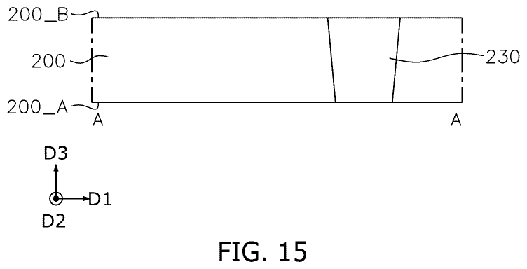

FIGS. 15 to 20 are diagrams illustrating intermediate stages of manufacturing a semiconductor device, which are provided to explain a method for manufacturing a semiconductor device according to some embodiments. For reference, FIGS. 15 to 20 may correspond to a cross-sectional view taken along line A-A of FIG. 1.

Referring to FIG. 15, the through isolation film 230 may be formed on (i.e., in) the second substrate 200.

In detail, a through hole penetrating the first surface 200_A and the second surface 200_B of the second substrate 200 may be formed on the second substrate 200. An insulating material may be formed in (e.g., may fill) the through hole to form the through isolation film 230.

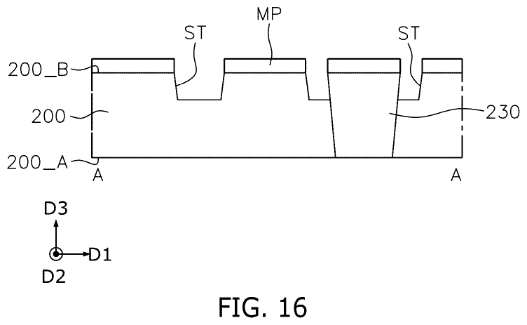

Referring to FIG. 16, the device isolation trench ST may be formed on the second surface 200_B of the second substrate 200. For example, the device isolation trench ST may be formed in the second substrate 200 adjacent to the second surface 200_B.

In detail, a mask pattern MP may be formed on the second surface 200_B of the second substrate 200. An etching process may be performed using the mask pattern MP as an etching mask. A portion of the second substrate 200 may be removed by an etching process, and a plurality of device isolation trenches ST may be formed. At least some of the plurality of device isolation trenches ST may be formed on the side surface of the through isolation film 230. The device isolation trench ST formed on the through isolation film 230 may expose a portion of the sidewall of the through isolation film 230.

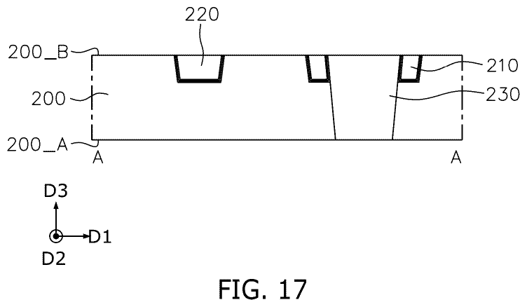

Referring to FIGS. 16 and 17, the first device isolation structure 210 and the second device isolation structure 220 may be formed on the device isolation trench ST.

Specifically, a pre-first liner film may be formed on the device isolation trench ST, the upper surface of the through isolation film 230, and the second surface 200_B of the second substrate 200. A pre-second liner film may be formed on the pre-first liner film. The pre-second liner film may be disposed along a profile of the pre-first liner film. A pre-filling film may be formed on the pre-second liner film. The pre-filling film may be on (e.g., may cover) the pre-second liner film. Portions of the pre-filling film, the pre-second liner film, and the pre-first liner film may be removed to form the first device isolation structure 210 and the second device isolation structure 220.

The first device isolation structure 210 may include a first liner film, a second liner film, and a filling film. Descriptions of the first liner film, the second liner film, and the filling film may be the same as those described with reference to FIGS. 1 to 5.

In the process of forming the through isolation film 230 on the second substrate 200, stress may be applied around the through isolation film 230. The lattice of the region around the through isolation film 230 of the second substrate 200 may be dislocated, and the transistor TR, etc. may thus not be disposed in the region around the through isolation film 230 (e.g., to avoid sacrificing reliability of the semiconductor device).

On the other hand, in the semiconductor device according to some embodiments, the region around the through isolation film 230 may be provided as a sacrificial layer for forming the first device isolation structure 210. The region around the through isolation film 230 may be etched to form the device isolation trench ST such that stress (e.g., stress applied to the active region of the transistor TR) caused by the process of forming the through isolation film 230 may be reduced. Accordingly, the reliability of the semiconductor device may be improved. In addition, by forming the transistor TR adjacent to the through isolation film 230, the integration density of the semiconductor device may be improved.

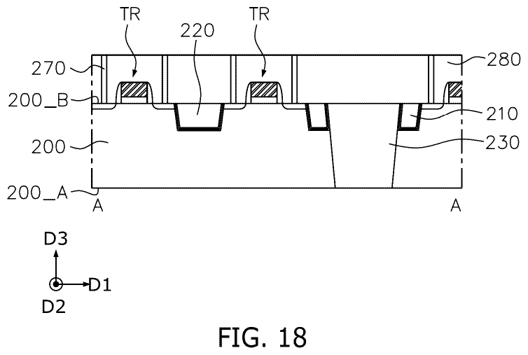

Referring to FIG. 18, the transistor TR and the upper contact via 270 may be formed on the second surface 200_B of the second substrate 200. At least some of the plurality of transistors TRs may be formed between the first device isolation structure 210 and the second device isolation structure 220.

The second interlayer insulating film 280 may be formed on the transistor TR. The upper contact via 270 penetrating the second interlayer insulating film 280 may be formed. However, embodiments of the present disclosure are not limited thereto. For example, the upper contact via 270 may be formed together with the through via 250 to be described below.

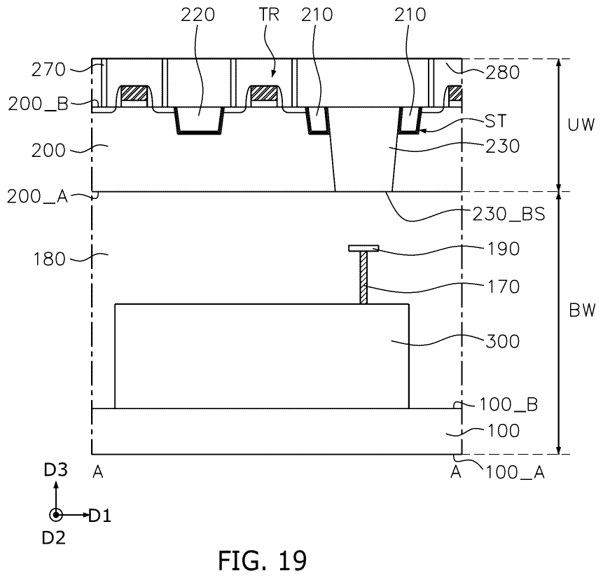

Referring to FIG. 19, an upper wafer UW may be connected onto a lower wafer BW.

The upper wafer UW may include the second substrate 200, the device isolation structures 210 and 220, the through isolation film 230, the upper contact via 270, the second interlayer insulating film 280, and the transistor TR.

The lower wafer BW may include the first substrate 100, the circuit device 300, the lower contact via 170, the lower wiring structure 190, and the first interlayer insulating film 180. The lower wafer BW may be manufactured by a separate process. Descriptions of the first substrate 100, the circuit device 300, the lower contact via 170, the lower wiring structure 190, and the first interlayer insulating film 180 of the lower wafer BW may be the same as those described with reference to FIGS. 1 to 5.

Specifically, the second substrate 200 and the through isolation film 230 may be connected to the first interlayer insulating film 180. The upper surface of the first interlayer insulating film 180 may be in contact with the first surface 200_A of the second substrate 200 and a lower surface of the through isolation film 230.

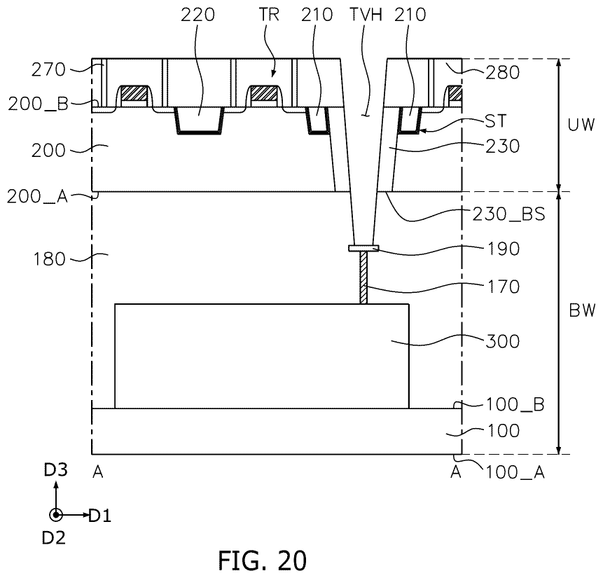

Referring to FIG. 20, a through via hole TVH penetrating a portion of the upper wafer UW and the lower wafer BW may be formed.

The through via hole TVH may penetrate the second interlayer insulating film 280 and the through isolation film 230. The through via hole TVH may penetrate a portion of the first interlayer insulating film 180. The through via hole TVH may extend in the third direction D3. A width of the through via hole TVH may decrease toward the first substrate 100. The through via hole TVH may expose a portion of the lower wiring structure 190.

Referring back to FIG. 2 and to FIG. 20, the through via 250 may be formed on the through via hole TVH. An insulating material may be stacked on the second interlayer insulating film 280 and the through via 250 such that a height of the second interlayer insulating film 280 may be increased.

Although example embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

1. A semiconductor device, comprising:
a first substrate;
a circuit device on the first substrate;
an interlayer insulating film on the circuit device;
a second substrate on the interlayer insulating film, wherein the second substrate includes a first surface adjacent to the interlayer insulating film and a second surface opposite to the first surface;
a device isolation trench in the second substrate and adjacent to the second surface;
a device isolation structure in the device isolation trench;
a through isolation film extending in the second substrate and the device isolation structure; and
a through via extending into the through isolation film and electrically connected to the circuit device.

2. The semiconductor device according to claim 1, wherein the device isolation structure comprises a first liner film, a second liner film, and a filling film sequentially stacked in the device isolation trench, and
wherein a portion of the first liner film is in contact with a sidewall of the through isolation film.

3. The semiconductor device according to claim 1, wherein the device isolation structure comprises a first liner film, a second liner film, and a filling film sequentially stacked in the device isolation trench, and
wherein a portion of the filling film is in contact with a sidewall of the through isolation film.

4. The semiconductor device according to claim 1, wherein at least a portion of the through isolation film is between the device isolation structure and the through via.

5. The semiconductor device according to claim 1, wherein a lower surface of the through isolation film is coplanar with the first surface of the second substrate, and
wherein the lower surface of the through isolation film is in contact with the interlayer insulating film.

6. The semiconductor device according to claim 1, wherein an upper surface of the through isolation film is coplanar with the second surface of the second substrate.

7. The semiconductor device according to claim 1, further comprising a transistor on the second surface of the second substrate, wherein the transistor is electrically connected to the circuit device through the through via.

8. The semiconductor device according to claim 1, wherein the device isolation structure at least partially surrounds the through isolation film.

9. The semiconductor device according to claim 1, wherein the circuit device comprises:
a plurality of cell channel patterns stacked in a first direction perpendicular to the second surface of the second substrate; and
a word line on the plurality of cell channel patterns and extending in a second direction intersecting the first direction, and
wherein the through via is electrically connected to the word line.

10. The semiconductor device according to claim 1, wherein a portion of the second substrate is between the device isolation structure and the through isolation film.

11. The semiconductor device according to claim 1, wherein the second substrate comprises a buffer region between the device isolation structure and the through isolation film, and
wherein the device isolation structure is spaced apart from the through isolation film.

12. A semiconductor device, comprising:
a first substrate;
a circuit device on the first substrate;
an interlayer insulating film on the first substrate and the circuit device;
a second substrate on the interlayer insulating film, wherein the second substrate includes a first surface in contact with the interlayer insulating film and a second surface opposite to the first surface;
a through isolation film extending in the second substrate;
a first device isolation structure in the second substrate and at least partially surrounding the through isolation film, wherein the first device isolation structure comprises a first liner film, a second liner film, and a filling film that are sequentially stacked; and
a through via extending into the through isolation film and electrically connected to the circuit device.

13. The semiconductor device according to claim 12, wherein portions of the first liner film and the second liner film extend along a sidewall of the through isolation film.

14. The semiconductor device according to claim 12, wherein the first device isolation structure is on opposing side surfaces of the through isolation film.

15. The semiconductor device according to claim 12, wherein the first device isolation structure overlaps the through isolation film in a direction parallel to the second surface of the second substrate.

16. The semiconductor device according to claim 12, further comprising:
a second device isolation structure in the second substrate and adjacent to the first device isolation structure; and
a transistor between the second device isolation structure and the first device isolation structure.

17. The semiconductor device according to claim 12, wherein an upper surface of the first device isolation structure and an upper surface of the through isolation film are coplanar.

18. The semiconductor device according to claim 12, further comprising a lower wiring structure in the interlayer insulating film,
wherein the circuit device comprises:
a plurality of cell channel patterns stacked in a first direction perpendicular to the second surface of the second substrate; and
a word line on the plurality of cell channel patterns and extending in a second direction intersecting the first direction, and
wherein the lower wiring structure electrically connects the word line to the through via.

19. The semiconductor device according to claim 12, further comprising a logic circuit on the second surface of the second substrate, wherein the logic circuit is configured to control the circuit device.

20. A semiconductor device, comprising:
a first substrate;
a circuit device on the first substrate, wherein the circuit device comprises a plurality of cell channel patterns stacked in a first direction perpendicular to an upper surface of the first substrate, a word line on the plurality of cell channel patterns and extending in a second direction parallel to the upper surface of the first substrate, and a bit line;
an interlayer insulating film on the first substrate and the circuit device;
a second substrate on the interlayer insulating film, wherein the second substrate includes a first surface in contact with the interlayer insulating film and a second surface opposite to the first surface;
a device isolation trench in the second substrate and adjacent to the second surface;
a device isolation structure in the device isolation trench, wherein the device isolation structure comprises a first liner film, a second liner film, and a filling film that are sequentially stacked;
a through isolation film extending in the second substrate and adjacent to the device isolation structure; and
a through via extending into the through isolation film and electrically connected to the word line,
wherein the device isolation structure at least partially surrounds the through isolation film.
